(19) United States
(12) Patent Application Publication
(10) Pub. No.: US 2011/0023933 A1
(43) Pub. Date: Feb. 3, 2011

(54) Interconnection Schemes for Photovoltaic Cells

(75) Inventor: Brian Josef Bartholomeusz, Palo Alto, CA (US)

Correspondence Address: BAKER BOTTS L.L.P., 2001 ROSS AVENUE, SUITE 600, DALLAS, TX, 75201-2980, US

(73) Assignee: APPLIED QUANTUM TECHNOLOGY, LLC, Santa Clara, CA (US)

(21) Appl. No.: 12/783,412

(22) Filed: May 19, 2010

Related U.S. Application Data
(60) Provisional application No. 61/230,241, filed on Jul. 31, 2009.

(51) Int. Cl. H01L 31/042; H01L 31/00; H01L 31/18

(52) U.S. Cl. 136/244; 136/256; 438/98; 257/E21.159

(57) ABSTRACT

In particular embodiments, a method is described for fabricating a photovoltaic cell and includes providing a substrate; depositing a bottom contact layer over the substrate; masking one or more portions of the bottom contact layer; depositing one or more photovoltaic absorber layers over the bottom contact layer; and depositing a top contact layer over the one or more photovoltaic absorber layers, wherein the one or more portions of the bottom contact layer are left exposed after depositing the one or more photovoltaic absorber layers and the top contact layer as a result of the masking thereby leaving the one or more portions of the bottom contact layer suitable for use as electrical contacts.

### RELATED APPLICATIONS

This application claims the benefit, under 35 U.S.C. §119(e), of U.S. Provisional Patent Application No. 61/230,241, entitled INTERCONNECTION SCHEMES FOR PHOTOVOLTAIC CELLS, filed 31 Jul. 2009, and hereby incorporated by reference herein.

### TECHNICAL FIELD

The present disclosure generally relates to photovoltaic devices, and more particularly to interconnection schemes for connecting photovoltaic cells.

### BACKGROUND

Conventional photovoltaic cells, such as crystalline silicon solar cells, are generally inter-connected using a process referred to as “tabbing and stringing” whereby conducting contacts of adjacent photovoltaic cells are electrically connected (tabbed) to form a chain of devices connected in series (the string). A number of these strings are then packaged together to form a module that is installed on rooftops or other power generating locations. In a majority of conventional photovoltaic cells, one of the conducting contacts of each cell is positioned along the bottom surface of a silicon wafer in the form of a metallic layer, which is typically made up of aluminum metal or an aluminum alloy. The top contact of the photovoltaic cell is typically a screen-printed and baked conductive grid formed using a metallic paste, for example. The current collection portion of this grid and the part that is used for inter-connection is generally referred to as the bus-bar. As shown in FIG. 1, individual photovoltaic cells 102 are typically connected by soldering a connection 104, such as a wire for example, between the bus-bar 106 on the top of one cell 102 with the metal surface of the bottom contact 108 at the bottom of the adjacent cell 102.

Not only do these interconnections (e.g., wires) require non-trivial additional space to be left between adjacent photovoltaic cells 102 but the distorted configuration (e.g., bends 110) can result in stresses and fatigue related failure during prolonged usage, particularly if subjected to significant thermal cycling. Additionally, this interconnection process (during module assembly of conventional silicon cells) is laborious and not readily automated. This has resulted in manufacturing inefficiencies and cost contributions.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 illustrates a diagrammatic cross-sectional side view of a conventional interconnection arrangement for silicon photovoltaic cells.

FIG. 2 illustrates a diagrammatic cross-sectional side view of an example interconnection arrangement for photovoltaic cells incorporating electrode access contacts.

FIG. 3 illustrates a flowchart illustrating an example method for fabricating photovoltaic cells having electrode access contacts.

FIG. 4 illustrates an example sample holder suitable for use in the method of FIG. 3.

FIG. 5 illustrates a diagrammatic top view of an example chain or string of photovoltaic cells.

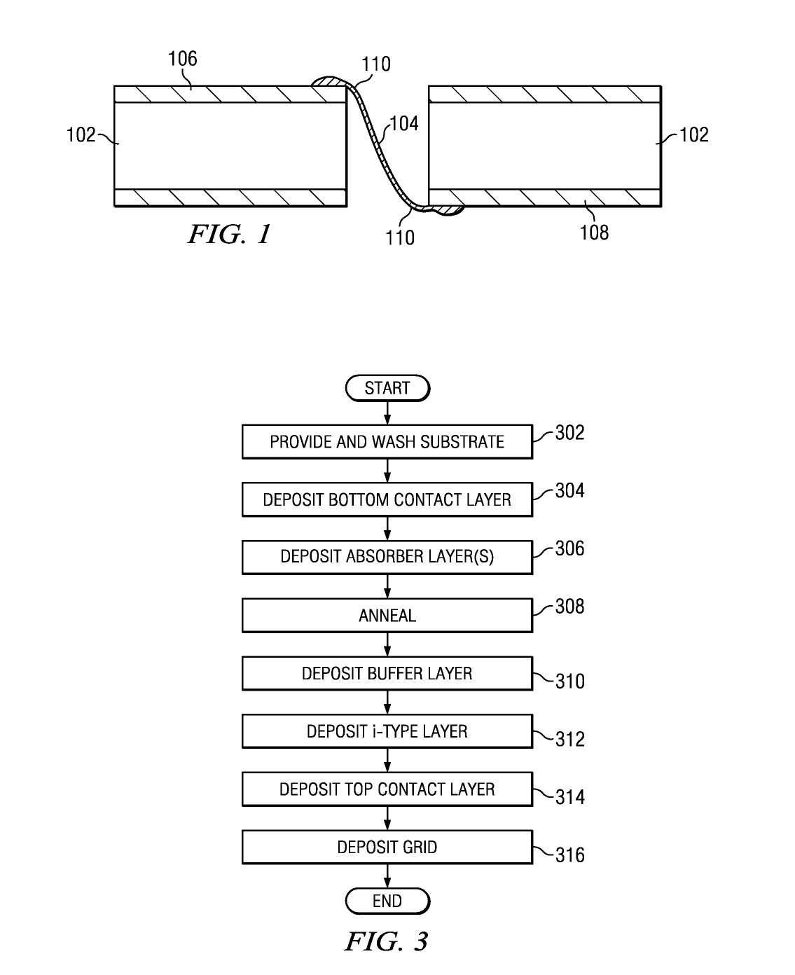

### DESCRIPTION OF EXAMPLE EMBODIMENTS

The present disclosure is now described in detail with reference to a few particular embodiments thereof as illustrated in the accompanying drawings. In the following description, numerous specific details are set forth in order to provide a thorough understanding of the present disclosure. It is apparent, however, to one skilled in the art, that particular embodiments of the present disclosure may be practiced without some or all of these specific details. In other instances, well known process steps and/or structures have not been described in detail in order to not unnecessarily obscure the present disclosure. In addition, while the disclosure is described in conjunction with the particular embodiments, it should be understood that this description is not intended to limit the disclosure to the described embodiments. To the contrary, the description is intended to cover alternatives, modifications, and equivalents as may be included within the spirit and scope of the disclosure as defined by the appended claims.

Particular embodiments relate to the formation, during nominal cell fabrication, of optimally sized and positioned Electrode Access Contacts (EACs) coupled to the top and bottom contacts of a, by way of example, conventionally shaped and sized thin film solar or photovoltaic (hereinafter photovoltaic) cell. In particular embodiments, the EACs are located and accessible on the top surface of each photovoltaic cell. Additionally, in particular embodiments, the EACs are distinctly formed such that they are readily identifiable by human or machine vision techniques, and thus can easily be distinguished for interconnection purposes. In various embodiments, the number, size, shape, and position of the EACs may vary according to whatever may be deemed optimal or most desirable for any particular photovoltaic cell.

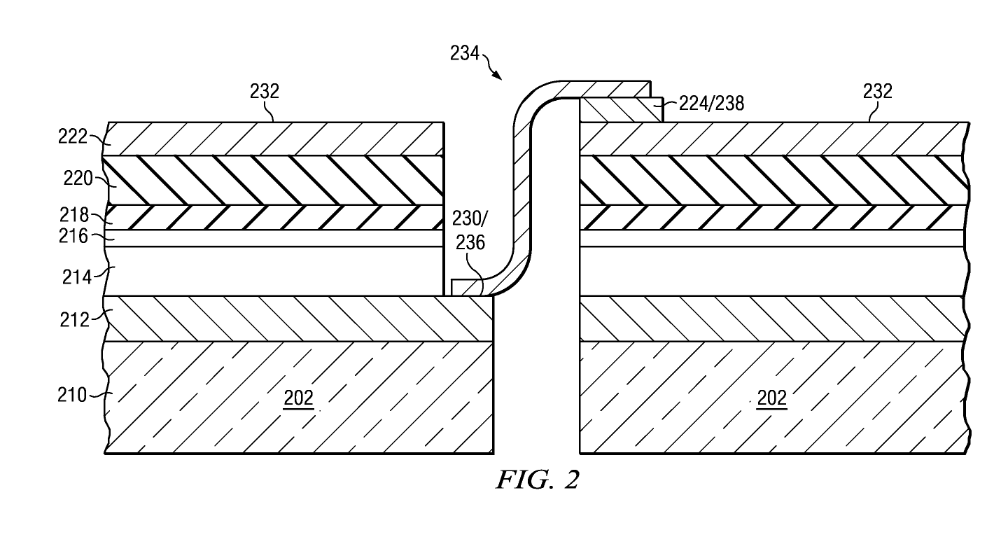

FIG. 2 illustrates a diagrammatic cross-sectional side view of an example interconnection arrangement for photovoltaic cells 202 incorporating EACs 236 and 238. In particular embodiments, photovoltaic cells 202 are thin film photovoltaic cells. By way of example, photovoltaic cells 202 may be Copper-Indium-disulfide (“CIS2”) based cells, Copper-Indium-diselenide (“CIS”) based cells, Copper-Indium-Gallium-diselenide (CuInₓGa₍₁₋ₓ₎Se₂, “CIGS”) based cells, or various chalcopyrite based thin film photovoltaic cells, among other suitable types of photovoltaic cells. In the illustrated embodiment, each photovoltaic cell 202 comprises a plurality of layers grown or otherwise deposited over a substrate 210.

FIG. 3 illustrates an example method for fabricating one or more photovoltaic cells 202. At step 302 a suitable substrate is provided and, in an example embodiment, washed with deionized water. In the illustrated embodiment, substrate 210 is a glass substrate (e.g., a soda lime float glass) having a thickness in the range of approximately 0.7 to 2.3 millimeters (mm), although other materials and thicknesses may be suitable. A conducting bottom contact layer 212 is deposited over substrate 210 at 304. By way of example and not by way of limitation, bottom contact layer 212 may be a Molybdenum layer having a thickness in the range of approximately 500 to 1000 nanometers (nm). At 306, absorber layer(s) 214 is deposited over bottom contact layer 212. By way of example and not by way of limitation, absorber layer 214 may be a p-type semiconducting layer. In some embodiments, absorber layer 214 may actually include a plurality of stacked layers. In particular embodiments, absorber layer 214 comprises one or more CIS, CIS2, or CIGS layers and has a total thickness in the range of approximately 1.2 to 3 micrometers (μm).

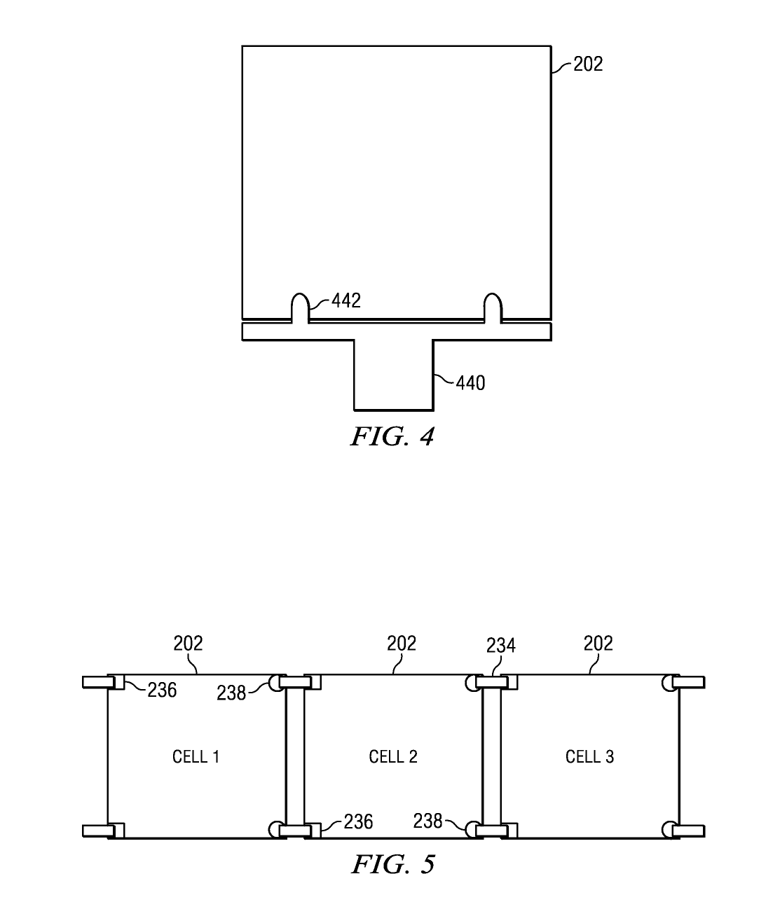

According to particular embodiments, while depositing absorber layer 214 and the subsequent layers described below, one or more portions of a peripheral edge of the substrate is selectively masked such that a portion of the bottom contact layer 212 is left exposed. As described below, the exposed portion of the bottom contact layer 212 serves as the bottom EAC 236 for the photovoltaic cell 202. The masking can be accomplished in a number of ways including relatively more complex ones such as photo-lithography, which is customarily used for semiconductor processing. However one preferred embodiment would utilize specially designed sample holders 440, as illustrated in FIG. 4, in conjunction with appropriate sample rotation or translation to selectively expose or hide the requisite portion of the photovoltaic cell 202 during fabrication. By way of example, stabilizing protrusions from sample holder 440 can additionally serve to mask selective regions on the sample surface at various stages of the fabrication process. In the case of a CIGS type cell 202 fabricated in a continuous in-line process, after the molybdenum bottom contact layer 212 has been deposited uniformly over the whole substrate surface, the substrate 210 is transferred to a sample holder 440 which obscures the EAC regions throughout the subsequent processing.

In particular embodiments, sample holder 440 includes integrally formed (with sample holder 440) masking protrusions or tabs (hereinafter “tabs”) 442. Masking tabs 442 selectively mask desired portions of bottom contact layer 212 that will subsequently form the bottom EACs 236. Although in the described embodiment, masking tabs 442 integral with the sample holder are used to selectively mask the desired portions of bottom contact layer 212, it should be appreciated that any suitable means may be used to mask the desired portions of bottom contact layer 212 to form the bottom EACs 236. In various embodiments, bottom contact layer 212 may be selectively masked to produce one or more bottom EACs 236 having any desired shape or size (although it is typically desirable to maximize the area of the subsequently deposited absorber layer to maximize the light absorbed by the photovoltaic cell 202). By way of example, in the illustrated embodiment, two bottom EACs 236 will be formed. In an alternate embodiment, an entire peripheral edge of the bottom contact layer 212 may be masked by a masking tab 442. It should be appreciated that, in this way, the bottom EACs 236 may be formed integrally or concurrently with the conventional fabrication of the photovoltaic cell 202.

Following deposition of the absorber layer 214, the substrate 210, bottom contact layer 212, and absorber layer 214 may be annealed at 308 and subsequently cooled. In particular embodiments, a buffer (window) layer 216 is then grown or otherwise deposited over absorber layer 214 at 310. Again, buffer layer 216 and the subsequently deposited layers described below are masked by masking tabs 442 thereby leaving portions of the bottom contact layer 212 exposed to form the bottom EACs 236 of the photovoltaic cell 202. By way of example and not by way of limitation, buffer layer 216 may be an n-type semiconducting layer formed from, by way of example, CdS or In₂S₃, among other suitable materials, and have a thickness in the range of approximately 30 to 70 nm.

In particular embodiments, an i-type layer 218 is grown or otherwise deposited over buffer layer 216 at 312. By way of example and not by way of limitation, i-type layer 218 may be formed from ZnO and have a thickness in the range of approximately 70 to 100 nm. At 314, a top contact layer 220 may then be deposited over the i-type layer 218. In particular embodiment, top contact layer 220 may be formed from a conducting material such as, by way of example and not by way of limitation, AZO (Al2O3 doped ZnO) or IZO (Indium Zinc Oxide, e.g., 90 wt % In2O3/10 wt % ZnO), and have a thickness in the range of approximately 0.5 to 1.5 μm.

In particular embodiments, an optional conducting grid 222 including bus bars 224 (which may be integrally formed with grid 222) is also deposited at 316 over the top contact layer 220. Any of the aforementioned layers may be deposited by any suitable means such as, by way of example, physical vapor deposition (PVD), including sputtering or evaporation, chemical vapor deposition (CVD), electroplating, plasma spraying, printing, solution coating, etc, while being held by sample holder 440 and selectively masked by masking tabs 442. Conventional processes such as edge isolation, deposition of an anti-reflective coating, and a light soaking, among others, may then follow prior to pre-testing, sorting, packaging, and shipping.

Those of skill in the art will appreciate that FIG. 2 is not to scale as the sum total of the thicknesses of layers 212, 214, 216, 218, 220, 222, and 224 is, in particular embodiments, still on the order of or less than 1% of the thickness of substrate 210, and thus on the order of or less than 1% of the thickness of the entire photovoltaic cell and may, in some embodiments, be less than one-tenth of 1% of the thickness of the entire photovoltaic cell.

As illustrated in FIG. 2, each photovoltaic cell 202 includes a recessed surface 230 on at least one peripheral edge of the photovoltaic cell (e.g., a side that will neighbor an adjacent photovoltaic cell). However, in particular embodiments and as just described, the recessed surface 230 may only be recessed from an absolute top surface 232 of the photovoltaic cell 202 by approximately 1% of the thickness of the entire photovoltaic cell 202, and may, in some particular embodiments, be recessed from the absolute top surface 232 by less than one-tenth of 1% of the thickness of the entire photovoltaic cell 202. Each exposed recessed surface 230 represents a top surface of the bottom contact layer 212 and forms and represents the bottom EAC 236 of each photovoltaic cell 202. Thus, for practical purposes, the top surfaces 230 of the bottom EACs 236 are approximately coplanar with the top surface of the top EAC 238 of the adjacent photovoltaic cell 202. In embodiments in which a grid 222 and bus bars 224 are not deposited, the top EAC 238 may be a portion of the top contact layer 220 itself or, alternately, a transparent conductive oxide that is located at the top-most surface of the cell over the top contact layer 220. Alternatively, if a top surface metal contact grid 220 is employed, the bus bar 224 or other portion of the grid 222 may form the top EAC 238 to optimally interface with the bottom EAC 236 of the adjacent cell 202. Again, as described above, the top and bottom EACs may take the form of discrete areas (as shown in FIG. 5 below) or as exposed strips along the cell periphery.

As illustrated in FIG. 2 and FIG. 5, which illustrates a chain or string of electrically connected photovoltaic cells 202, an interconnect 234 electrically connects each bottom EAC 236 of one photovoltaic cell 202 with the top EAC 238 of the immediately adjacent photovoltaic cell 202 and so on to form an electrically connected chain or string of photovoltaic cells 202. By way of example, the interconnect may be a wire or metallic tab that bridges the gap between the bottom EAC 236 of one cell 202 and the top EAC 238 of the neighboring cell. Due to the flexibility in placement of the contacts 236 and 238, these can be located anywhere on the surface and facilitate non-linear interconnection schemes. Additionally, although in the illustrated embodiment the interconnect 234 is shown with two bends, it should be appreciated that this is not to scale and that the bends in the interconnect (if any) will generally not be visible with the naked eye as the bottom EAC 236 of one cell is virtually coplanar with the top EAC 238 of the neighboring cell. In this way, the interconnect is significantly less susceptible to stresses as a result of thermal cycling during operation of the photovoltaic cells 202.

Furthermore, in some embodiments, an entire peripheral edge of the bottom contact layer 212 may be masked by a masking tab 442 such that the bottom EAC 236 extends along most or all of one or more sides of the photovoltaic cell 202. In such an embodiment, a single tab may be used to electrically an entire side of the bottom contact layer 212 of one cell with an entire side (e.g. bus bar 224) of the adjacent cell. Not only would this interconnection arrangement be even less susceptible to stresses, but it may also provide a physical barrier that seals the space between the adjacent cells. In one embodiment, this sealed space may then be injected or otherwise filled with a filler material.

The interconnects 234 may be applied with any suitable means including soldering, bonding, ultrasonic bonding/welding, etc. One advantage of using the EACs described is that it would be amenable to novel interconnection schemes in which the interconnections 234 are embedded in a top cover material, for example, in some designated pattern. By way of example, the interconnections 234 may be laid out in a pattern that corresponds to the desired layout of the chain of photovoltaic cells 202. The pattern of interconnects 234 may then be positioned simultaneously over the pattern of photovoltaic cells, or vice versa. In this case all of the photovoltaic cells 202 of a given module may be interconnected in a single-step process through laser or ultrasonic welding or some similar process.

In conclusion, a major advantage of this interconnection scheme would be its ease of automation and the fact that the interconnections themselves would be co-planar and relatively stress-free. The EACs and interconnections would also permit very high packing densities to be achieved due to the absence of connections running over and under adjacent cells.

In particular embodiments, photovoltaic cells 202 are fabricated on relatively smaller-sized substrates such that they will have the general appearance and dimensions of conventional silicon solar cells (for example, square or pseudo-square 157 mm² or 210 mm² cells), although other arrangements may be suitable. In particular embodiments, this facilitates their use as drop-in replacements for equivalent sized and shaped silicon-based cells and as such will be compatible with the large global installed base of solar module manufacturers.

The present disclosure encompasses all changes, substitutions, variations, alterations, and modifications to the example embodiments described herein that a person having ordinary skill in the art would comprehend. Similarly, where appropriate, the appended claims encompass all changes, substitutions, variations, alterations, and modifications to the example embodiments described herein that a person having ordinary skill in the art would comprehend.

What is claimed is:

1. A photovoltaic cell, comprising:
a substrate;
a bottom contact layer positioned over the substrate;
one or more photovoltaic absorber layers positioned over the bottom contact layer; and
a top contact layer positioned over the one or more photovoltaic absorber layers;
wherein one or more portions of the bottom contact layer are exposed on a top surface thereof to provide one or more electrical contacts to the bottom contact layer, the one or more electrical contacts being suitable for electrical connection with a top conducting surface of an adjacent photovoltaic cell when the photovoltaic cell is positioned adjacent the adjacent photovoltaic cell.

2. The photovoltaic cell of claim 1, wherein a top surface of each of the one or more electrical contacts is approximately coplanar with a top surface of the photovoltaic cell relative to the thickness of the substrate.

3. The photovoltaic cell of claim 1, wherein each of one or more of the one or more photovoltaic absorber layers comprises one or more Copper-Indium-disulfide (CIS2) material layers, one or more Copper-Indium-diselenide (CIS) material layers, or one or more Copper-Indium-Gallium-diselenide (CIGS) material layers.

4. The photovoltaic cell of claim 1, wherein the one or more photovoltaic absorber layers comprise one or more p-type semiconducting layers.

5. The photovoltaic cell of claim 1, wherein the substrate is a glass substrate.

6. The photovoltaic cell of claim 1, wherein the bottom contact layer comprise a Molybdenum metallic layer.

7. The photovoltaic cell of claim 1, further comprising a buffer layer deposited over the one or more photovoltaic absorber layers and under the top contact layer.

8. The photovoltaic cell of claim 7, wherein the buffer layer comprises an n-type semiconducting material.

9. The photovoltaic cell of claim 7, further comprising an i-type oxide layer deposited over the buffer layer and under the top contact layer.

10. The photovoltaic cell of claim 1, further comprising an electrically conductive grid deposited over the top contact layer.

11. The photovoltaic cell of claim 1, wherein a combined total thickness of the one or more photovoltaic absorber layers and the top contact layer and any layers in between is less than one percent of the thickness of the substrate.

12. A method, comprising:
depositing a bottom contact layer over a suitable substrate;
masking one or more portions of the bottom contact layer;
depositing one or more photovoltaic absorber layers over the bottom contact layer; and
depositing a top contact layer over the one or more photovoltaic absorber layers, wherein the one or more portions of the bottom contact layer are left exposed after depositing the one or more photovoltaic absorber layers and the top contact layer as a result of the masking thereby leaving the one or more portions of the bottom contact layer suitable for use as electrical contacts.

13. The method of claim 12, wherein the masking comprises using photolithography to selectively remove the portions of the one or more photovoltaic absorber layers and the top contact layer and any layers therebetween such that the one or more portions of the bottom contact layer are exposed.

14. The method of claim 12, wherein the masking comprises using a sample holder that comprises one or more protrusions that each cover a portion of the bottom contact layer during the deposition of the one or more photovoltaic absorber layers and the top contact layer and any layers therebetween such that the one or more portions of the bottom contact layer are exposed after depositing the one or more photovoltaic absorber layers and the top contact layer and any layers therebetween.

15. The method of claim 12, further comprising annealing the substrate, the bottom contact layer, and the one or more photovoltaic layers after deposition of the one or more photovoltaic absorber layers and prior to deposition of the top contact layer.

16. The method of claim 12, further comprising depositing a buffer layer over the one or more photovoltaic absorber layers and under the top contact layer, wherein the one or more portions of the bottom contact layer are left exposed after depositing the one or more photovoltaic absorber layers, the buffer layer, and the top contact layer as a result of the masking thereby leaving the one or more portions of the bottom contact layer suitable for use as electrical contacts.

17. The method of claim 16, further comprising depositing an i-type oxide layer over the buffer layer and under the top contact layer, wherein the one or more portions of the bottom contact layer are left exposed after depositing the one or more photovoltaic absorber layers, the buffer layer, the i-type oxide layer, and the top contact layer as a result of the masking thereby leaving the one or more portions of the bottom contact layer suitable for use as electrical contacts

18. The method of claim 12, further comprising depositing an electrically conductive grid over the top contact layer.

19. The method of claim 12, wherein each of one or more of the one or more photovoltaic absorber layers comprises one or more Copper-Indium-disulfide (CIS2) material layers, one or more Copper-Indium-diselenide (CIS) material layers, or one or more Copper-Indium-Gallium-diselenide (CIGS) material layers.

20. A photovoltaic module, comprising:
a plurality of photovoltaic cells, each photovoltaic cell comprising:
a substrate;
a bottom contact layer positioned over the substrate;
one or more photovoltaic absorber layers positioned over the bottom contact layer; and
a top contact layer positioned over the one or more photovoltaic absorber layers;
wherein one or more portions of the bottom contact layer are exposed on a top surface thereof to provide one or more electrical contacts to the bottom contact layer, the one or more electrical contacts being suitable for electrical connection with a top conducting surface in electrical contact with a top contact layer of an adjacent one of the plurality of photovoltaic cells when the photovoltaic cell is positioned adjacent the adjacent one of the plurality of photovoltaic cells; and
a plurality of interconnections, each interconnection electrically connecting an exposed portion of the bottom contact layer of one of the plurality of photovoltaic cells with the top conducting surface of an adjacent one of the plurality of photovoltaic cells.
